(19) United States
(12) Patent Application Publication
(10) Pub. No.: US 2006/0283012 A1
(43) Pub. Date: Dec. 21, 2006

(54) Apparatus and method for solder ball placement

(75) Inventor: Jin-woo Lee, Yongin-si (KR)

Correspondence Address: GARDNER CARTON & DOUGLAS LLP;ATTN: PATENT DOCKET DEPT., 191 N. WACKER DRIVE, SUITE 3700, CHICAGO, IL, 60606, US

(73) Assignee: Samsung Techwin Co., Ltd., Changwon-city (KR)

(21) Appl. No.: 11/250,334

(22) Filed: Oct. 13, 2005

(30) Foreign Application Priority Data
Jun. 18, 2005 (KR) 10-2005-0052734

(51) Int. Cl. H05K 3/10; B23K 20/08

(52) U.S. Cl. 29/846; 29/840; 29/729; 228/33

(57) ABSTRACT

A solder ball-inspecting apparatus for a semiconductor component includes: a solder ball reservoir receiving a plurality of solder balls; a solder ball-transmitting tool provided with a plurality of ball-receiving apertures to which the solder balls received in the solder ball-reservoir are adhered and from which the adhered solder balls are separated to allow the solder balls to be seated on the semiconductor component; at least one electric pattern linearly interconnecting the ball-receiving apertures and having first and second ends that are to be electrically interconnected when the solder balls are correctly received in the respective solder ball-receiving apertures; an electric connection-detecting unit detecting electric connection of the electric pattern; and a determining-processing unit determining if the solder balls are corrected adhered to the ball-receiving apertures according to a detecting result of the electric connection-detecting unit.

### CROSS-REFERENCE TO RELATED PATENT APPLICATIONS

This application claims the benefit of Korean Patent Application No. 10-2005-0052734, filed on Jun. 18, 2005, in the Korean Intellectual Property Office, the disclosure of which is incorporated herein in its entirety by reference.

### BACKGROUND OF THE INVENTION

1. Field of the Invention

The present invention relates generally to a solder ball-inspecting apparatus and method, and more particularly to an apparatus and method for placing a solder ball that can quickly and accurately determine if a solder ball is correctly retained in a receiving aperture prior to placement.

2. Description of the Related Art

A flip chip package is manufactured by connecting pads disposed on a chip or wafer to a semiconductor package substrate using a bump instead of by connecting a semiconductor chip to a lead frame using a gold wire.

One of methods for making such a flip chip package is to use a solder ball bump. The solder ball bump may be manufactured by, for example, (a) transferring flux on a desired portion of a semiconductor chip or wafer, (b) locating a solder ball using a nozzle, and (c) welding the solder ball using a reflow-oven.

Such a solder ball bump manufacturing method has an advantage in productivity and uniformity as a plurality of pins (solder balls) are adhered to a chip or wafer at a time. However, since the defectiveness in the soldering process is determined by a state of solder balls that are primarily formed on the chip or wafer, there is a need to inspect the state of the solder balls.

A typical apparatus for inspecting placement of solder balls uses a camera. That is, as shown in FIG. 1, an apparatus for inspecting solder ball placement includes a light source 15, a camera 13, a table 11, and an image-processing unit 19. A semiconductor board 1, on which solder balls 3 are formed, is loaded on the table 11 that is designed to be movable leftward and rightward through a light beam that is produced by the light source 15. The camera 13 takes a photograph of an image that is reflected from the illuminated solder balls 3 and transmits the photographed image to the image-processing unit 19. The image-processing unit 19 analyses the photographed image to obtain information on the solder balls 3 such as the presence or absence thereof, location, pitch, and size of the solder balls 3, thereby identifying the uniformity and state of the solder balls 3.

However, since a solder ball is formed in a spherical-like shape, there may be a shadow or shading proximate one or more solder balls 3 when the camera 13 photographs the image. This makes it difficult to accurately determine the location of one or more of the solder balls 3. Therefore, a high resolution camera is required. Particularly, in recent years, the size of the package (e.g., semiconductor board, integrated circuit chip, etc.) has been reduced and thus the size of solder ball or bump has been reduced accordingly. Due to this size reduction, an even higher resolution camera is required.

Furthermore, when the area of the electrode pad is large or the number of electrode pads is increased, the recognition speed of the camera or the inspection speed of the image-processing unit is reduced due to the time required for analyzing a high resolution image.

### SUMMARY OF THE INVENTION

The present invention provides an apparatus and method for inspecting solder ball placement that can accurately and quickly determine if a solder ball is correctly retained in a ball-receiving aperture that is formed on a solder ball-transmitting tool. The present invention obviates the need of a camera for determining correct solder ball placement.

The present invention also provides an apparatus for transmitting a solder ball employing the apparatus and method for inspecting solder ball placement.

According to an aspect of the present invention, an apparatus for inspecting a solder ball that is placed on a semiconductor component includes a solder ball-transmitting tool, an electric pattern, an electric connection-detecting unit, and a determining-processing unit. The solder ball-transmitting tool is provided with a plurality of ball-receiving apertures in which a plurality of solder balls is received from a solder ball-reservoir. The adhered solder balls are separated from the ball-receiving apertures to place or seat the solder balls on the semiconductor component. The electric pattern interconnects the plurality of ball-receiving apertures and has first and second ends that are electrically interconnected when the plurality of solder balls are correctly received in the plurality of solder ball-receiving apertures. The electric connection-detecting unit detects electric connection of the electric pattern. The determining-processing unit determines if the solder balls are corrected adhered to the ball-receiving apertures according to an output of the electric connection-detecting unit.

The electric pattern may be made up of a plurality of unit patterns, each of which is configured to interconnect two adjacent ball-receiving apertures.

The plurality of unit patterns may be configured or otherwise arranged to interconnect all of the ball-receiving apertures formed on the solder ball-transmitting tool.

The determining-processing unit determines that the solder balls are correctly received in the solder ball-receiving apertures when opposite ends of the electric pattern are electrically interconnected. The determining-processing unit determines that the solder balls are not correctly received in the solder ball-receiving apertures when opposite ends of the electric pattern are not electrically interconnected.

According to another aspect of the present invention, an apparatus for transmitting a solder ball to a semiconductor component includes a solder ball-reservoir, a solder ball-transmitting tool, and a solder ball-transferring member. The solder ball-reservoir receives a plurality of solder balls. The solder ball-transmitting tool is provided with a plurality of ball-receiving apertures to which the solder balls of the solder ball-reservoir are adhered and from which the adhered solder balls are separated to place or seat the solder balls on the semiconductor component. An electric pattern interconnects the ball-receiving apertures. The solder ball-transferring member causes the solder balls to be received in and released from the solder ball-receiving apertures that are formed on the solder ball-transmitting tool.

The electric pattern may include at least one unit pattern that continuously interconnects adjacent ball-receiving apertures.

The apparatus for transmitting a solder ball may further include an electric connection-detecting unit detecting electric connection of the electric pattern; and a determining-processing unit determining if the solder balls are correctly adhered to the ball-receiving apertures according to a detecting result or output of the electric connection-detecting unit.

The solder ball-transferring member is designed to increase adhering force of the solder balls to the solder ball-receiving apertures when it is determined that the solder balls are not correctly received in the solder ball-receiving apertures.

The apparatus for transmitting a solder ball may further include a ball-bridging detecting unit that detects whether the solder balls being retained in the ball-receiving apertures are adhered to each other. Further, the apparatus may include a ball-separating unit for separating the bridged balls from each other.

The ball-bridging detecting unit may include a sensor arranged beside the ball-receiving aperture at a height equal to or slightly lower than a bottom of the solder ball that is correctly received in the ball-receiving aperture.

The ball-separating unit may include a blowing member for separating the bridged-balls from each other by blowing fluid to the bridged balls.

Force of the blowing fluid is lower than a force that may separate the solder balls from the ball-receiving apertures.

According to still another aspect of the present invention, there is provided a solder ball-inspecting method including: electrically interconnecting the ball-receiving apertures by adhering respective solder balls to the ball-receiving apertures; detecting if ball-receiving apertures are electrically interconnected; and determining if the solder balls are correctly adhered to the respective ball-receiving apertures in accordance with the electric connection-detecting result.

The electrically interconnecting of the ball-receiving apertures may include forming a single unit pattern interconnecting the adjacent ball-receiving apertures or forming at least one electric pattern comprised of a plurality of unit patterns that are continuously connected to each other and the electric connection between the ball-receiving apertures are determined by detecting if opposite ends of the electric pattern are electrically interconnected.

When the opposite ends of the electric pattern are electrically interconnected, it is determined that the solder balls are correctly adhered to the ball-receiving apertures and when the opposite ends of the electric pattern are not electrically interconnected, it is determined that the solder balls are not correctly adhered to the ball-receiving apertures.

The adhering respective solder balls to the ball-receiving apertures may include forming the plurality of ball-receiving apertures such that a subset of ball-receiving apertures in the plurality are configured in groups wherein each group is subject to an independent adhering force and forming a plurality of electric patterns interconnecting the ball-receiving aperture groups and the determining if the solder balls are correctly adhered to the respective ball-receiving apertures includes applying first adhering force to a ball-receiving aperture group connected to an electric pattern having opposite ends that are not electrically interconnected, the first adhering force being higher than second adhering force applied to another ball-receiving group connected to an electric pattern having opposite ends that are electrically interconnected.

The method may further includes, after adhering the solder balls to the ball-receiving apertures, detecting if at least two solder balls are adhered to each other and separating the adhered balls from each other.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a conventional solder ball-inspecting apparatus;

FIG. 2 is a sectional view of a solder ball-inspecting apparatus according to an embodiment of the present invention and a semiconductor component on which solder balls are loaded;

FIG. 3A is an enlarged sectional view of a portion A of FIG. 2 when the ball-receiving apertures are electrically interconnected;

FIG. 3B is an enlarged sectional view of a portion A of FIG. 2 when the ball-receiving apertures are not electrically interconnected;

FIG. 4 is a block diagram illustrating a plan view of a solder ball-inspecting apparatus when the ball-receiving apertures are electrically interconnected;

FIG. 5 is a block diagram illustrating a plan view of a solder ball-inspecting apparatus when the ball-receiving apertures are not electrically interconnected;

FIG. 6 is a block diagram illustrating a plan view of a modified example of FIG. 5;

FIG. 7 is a sectional view of a solder ball-transmitting apparatus according to an embodiment of the present invention;

FIG. 8 is a block diagram illustrating a plan view of a solder ball-transmitting apparatus when the ball-receiving apertures are electrically interconnected;

FIG. 9 is a sectional view of a structure for separating a surface on which ball-receiving apertures are formed and solder balls that are ball-bridged;

FIG. 10 is a flowchart of a solder ball-inspecting method according to an embodiment of the present invention; and

FIG. 11 is a flowchart illustrating a process for separating bridged solder balls in a solder ball-inspecting method of the present invention.

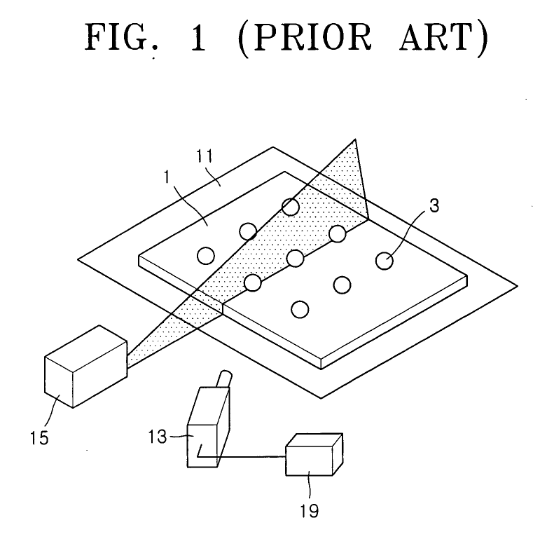

### DETAILED DESCRIPTION OF THE EMBODIMENTS

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity.

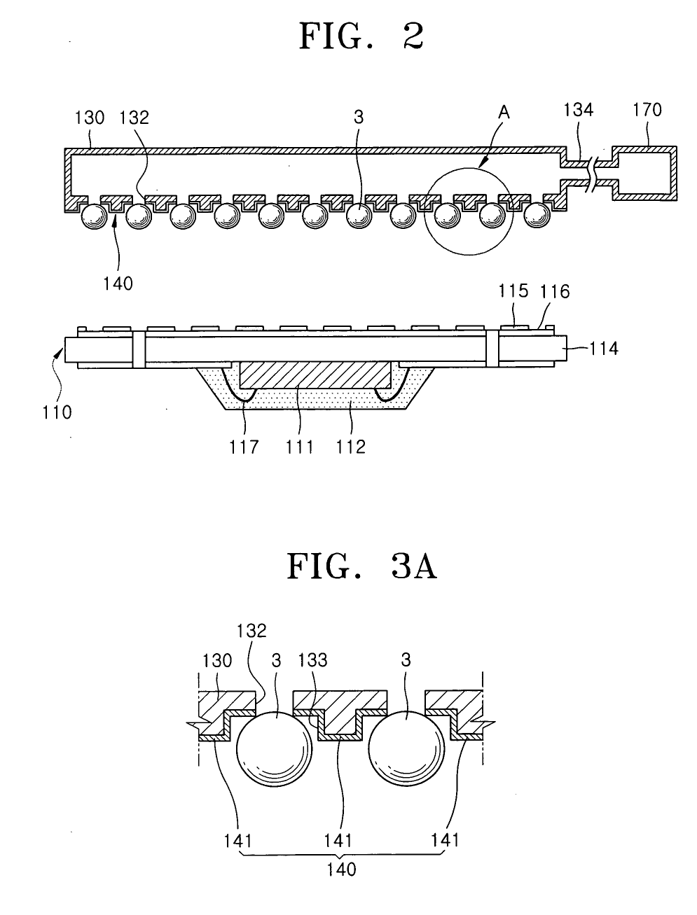

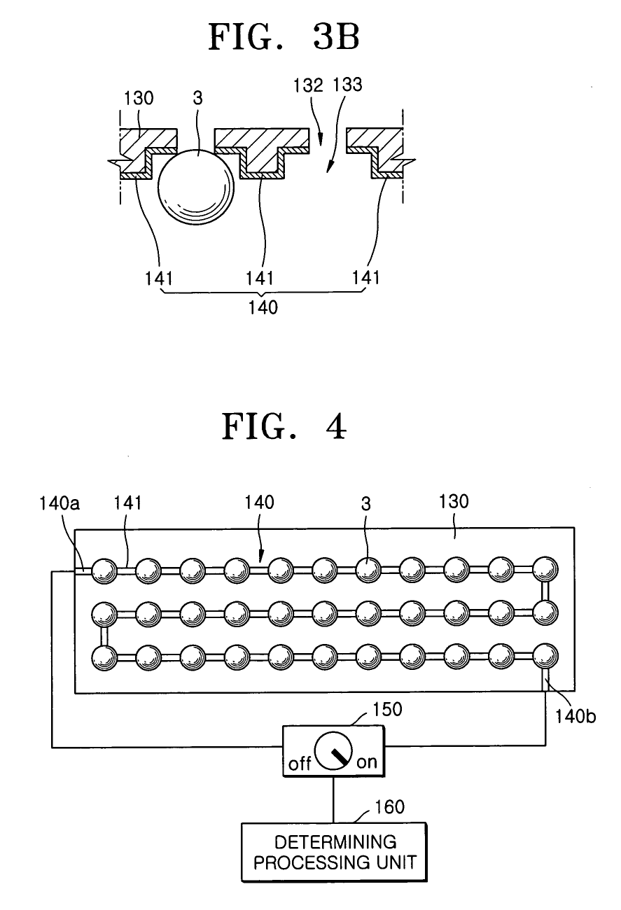

FIG. 2 is a sectional view of a solder ball-inspecting apparatus according to an embodiment of the present invention and a semiconductor component on which solder balls are loaded. FIG. 3A is an enlarged sectional view of a portion A of FIG. 2 when electric current is applied between the ball-receiving apertures. FIG. 3B is an enlarged sectional view of a portion A of FIG. 2 when electric current is not applied between the ball-receiving apertures. FIG. 4 is a block diagram of a solder ball-inspecting apparatus when electric current is applied between the ball-receiving apertures.

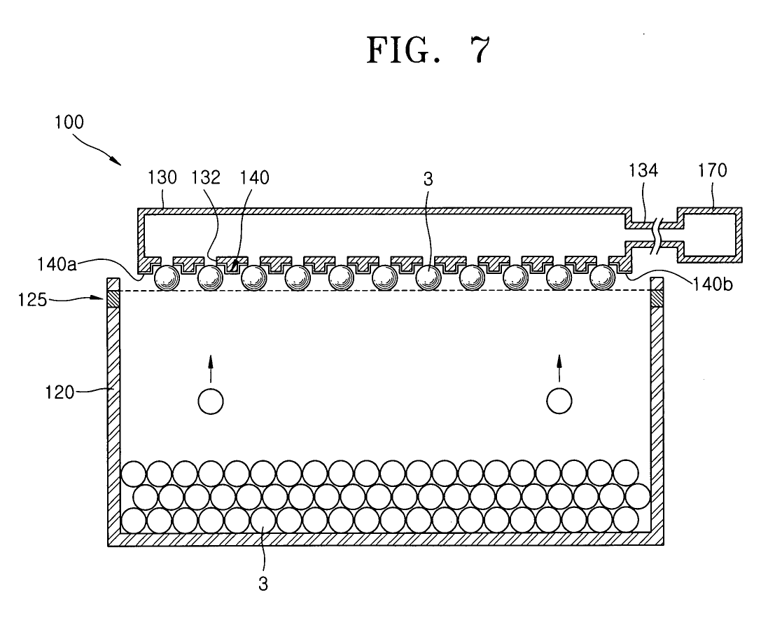

Referring now to FIGS. 2 through 4, the inventive solder ball-inspecting apparatus includes a solder ball-transmitting tool 130, at least one electric pattern 140, an electric connection detecting unit 150, and a determining processing unit 160. The solder ball-transmitting tool 130 functions to dispose, transmit or otherwise place solder balls 3, for example, solder balls 3 that are received from a solder ball-reservoir as indicated by reference numeral 120 in FIG. 7, on a semiconductor component 110 after receiving and retaining the solder balls 3. Here, as shown in FIG. 2, the semiconductor component 110 may be a printed circuit board. Alternatively, the semiconductor component may be a semiconductor wafer, and in this case, an electrode pad is formed on a surface of the semiconductor wafer. After mounting the solder balls 3 on the electrode pad, the semiconductor wafer may be separated into a plurality of dies such as circuit substrates for integrated circuit (IC) chips.

Ball-receiving apertures 132 are formed on the solder ball-transmitting tool 130. The solder balls 3 are adhered to the receiving apertures 132. Next, the solder balls that are adhered to the ball-receiving apertures 132 are separated from the ball-receiving apertures 132 and loaded on the semiconductor component 110.

This will be described with reference to FIG. 2, in which the solder ball-transmitting tool 130 is for a BGA package that loads the solder balls on a first surface of the printed circuit board, a second surface of which is wire-bonded via wire 117 to a semiconductor chip 111. Referring to FIG. 2, a solder ball mask layer 115 and solder ball-seating portions 116 are formed on a surface of the printed circuit board 114. The solder balls 3 are adhered to the solder ball-seating portions 116. That is, the solder ball-transmitting tool 130 for the BGA package is located above the printed circuit board 114 to dispose the solder balls 3 on the solder ball-seating portions 116 provided on the printed circuit board 114.

Describing in more detail, the solder ball-transmitting tool 130 is provided with a plurality of ball receiving apertures 132 for receiving a plurality of solder balls 3. A vacuum hole 134 is provided in the tool 130 for applying vacuum pressure from solder ball-transferring member 170 to apertures 132, thereby retaining the solder balls 3 that are received in the ball-receiving apertures 132. When the solder ball-transmitting tool 130 is disposed over the printed circuit board 114 and the locations of the solder balls 3 that are retained in the ball-receiving apertures 132 are aligned to the solder ball-seating portion 116, the vacuum pressure applied to the solder balls 3 through the vacuum hole 134 is released so that the solder balls 3 can be transmitted, positioned, disposed, arranged or the like on the solder ball-seating portions 116. Then, when the solder balls 3 are heated at a predetermined temperature, a surface layer of each solder ball 3 is molten to be adhered to the solder ball seating portion 116 formed on the printed circuit board 114.

The electric pattern 140 is formed on the surface of the solder ball-transmitting tool 130 in communication with the plurality of ball-receiving apertures 132. The electric pattern 140 is configured as a plurality of conductive pattern units 141 interconnecting the plurality of ball-receiving apertures 132. Thus, the electric pattern 140 is a discontinuous electrical path (i.e., an open circuit) that is made continuous (i.e., a closed circuit) by proper reception of the plurality of electrically conductive solder balls 3 within the plurality of ball-receiving apertures 132.

That is, as shown in FIG. 3A, when the solder balls 3 are correctly adhered to the respective ball-receiving apertures 132, two adjacent pattern units 141 are electrically connected to each other by a solder ball 3. On the contrary, as can be appreciated from FIG. 3B, when a solder ball 3 is not correctly adhered to the respective ball-receiving apertures 132, the adjacent pattern units 141 are not electrically connected to each other.

The electric pattern 140 includes a plurality of unit patterns 141 which are electrically interconnected by way of properly retained solder balls 3 disposed in adjacent receiving apertures 132. Ball-seating walls 133 (FIGS. 3A, 3B) which directly contact the outer surface of solder balls 3 are illustrated as having perpendicular top and side walls such that the apertures 132 are generally parallelepiped-shaped, but may be configured to have any suitable shape and size for retaining the solder balls 3.

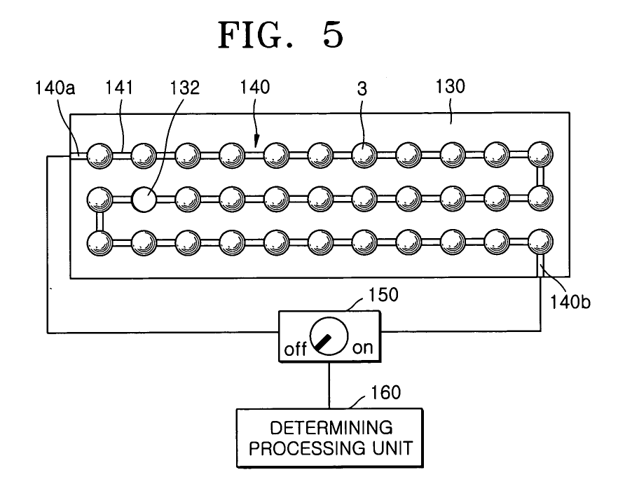

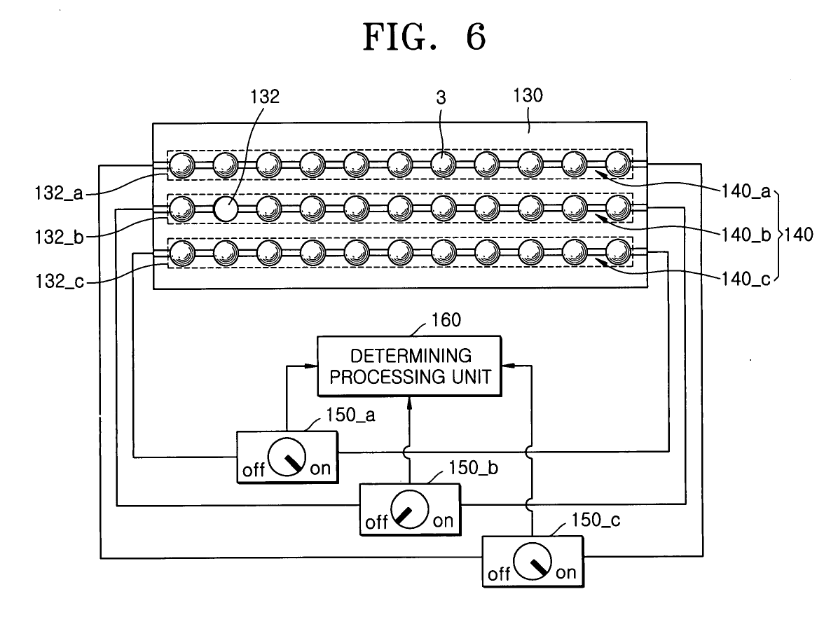

As shown in FIGS. 4 and 5, the electric pattern 140 may be designed to interconnect all of the ball-receiving apertures 132 formed on the solder ball-transmitting tool 130. Alternatively, as shown in FIG. 6, the electric pattern 140 may be designed to partly interconnect a group or subset of the plurality of ball-receiving apertures 132. Thus, as can be appreciated, separating the plurality of apertures 132 into groups helps a user identify the location of one or more improperly-seated (or missing) solder ball 3.

The electric connection of the electric pattern 140 (i.e., circuit continuity of the unit patterns 141) is, as shown in FIGS. 4 and 5, detected by the electric connection-detecting unit 150. That is, the electric connection-detecting unit 150 detects if first and second ends 140a and 140b of the electric pattern 140 are electrically interconnected through the plurality of unit patterns 141 and plurality of solder balls 3. In this case, the electric pattern 140 is formed of a plurality of single unit patterns 141, but depending on the configuration of apertures 132, fewer or additional unit patterns 141 may be provided.

The determining-processing unit 160 determines if the solder balls 3 are correctly received, seated or otherwise retained in the respective ball receiving apertures 132 in accordance with the detecting results or output of the electric connection-detecting unit 150. That is, when the first and second ends 140a and 140b of the electric pattern 140 are electrically interconnected through the plurality of unit patterns 141 and plurality of solder balls 3 as shown in FIG. 4, the determining-processing unit 160, relative to the output from electric connection-detecting unit 150, determines that the solder balls 3 are correctly received in the respective ball receiving apertures 132. When the first and second ends 140a and 140b of the electric pattern 140 are not electrically interconnected as shown in FIG. 5 (a solder ball is missing from the second position from the left in the middle row), the determining-processing unit 160 determines that at least one of the solder balls 3 is not correctly received in the corresponding ball receiving aperture 132.

Therefore, it becomes possible to determine if the solder balls 3 are correctly received in the respective solder ball-receiving apertures 132 obviating the need for visual inspection by, for example a camera. Particularly, according to the present invention, there is no need to process the solder ball image taken by the camera. That is, by simply determining the electric connection of the electric pattern 140, it can be quickly and accurately determined if the solder balls 3 are correctly received in the respective solder ball-receiving apertures 132.

In this case, the electric connection-detecting unit 150 may include a current meter detecting a current difference between the first and second ends of the electric pattern 140. In this case, the current meter determines that the solder balls 3 are correctly received in the respective ball-receiving apertures 132 when a predetermined current is detected. The current meter determines that the solder balls 3 are not correctly received in the respective ball-receiving apertures 132 when no current is detected. Indeed, the electric connection-detecting unit 150 may be other devices known in the art such as a continuity testing means, voltage meter and the like.

As shown in FIG. 6, the electric pattern 140 comprises three groups of electric patterns 140_{—}a, 140_{—}b and 140_{—}c, but fewer or additional patterns may be provided on a single solder ball-transmitting tool 130. In this case, the electric patterns 140_{—}a, 140_{—}b and 140_{—}c are designed to linearly interconnect ball receiving aperture groups or rows indicated as 132_{—}a, 132_{—}b and 132_{—}c that are comprised of a part of the ball-receiving apertures 132 formed on the solder ball-transmitting tool 130.

The electric patterns 140_{—}a, 140_{—}b and 140_{—}c may be designed to interconnect the ball-receiving apertures 132 arranged in lateral or longitudinal directions. Alternatively, the electric patterns 140_{—}a, 140_{—}b and 140_{—}c may be formed to define a single circle. Other arranging patterns will be possible, for example, polygonal shapes and other regular and irregular arrangements of apertures 132.

The electric patterns 140_{—}a, 140_{—}b and 140_{—}c are connected to respective electric connection-detecting units 150_{—}a, 150_{—}b and 150_{—}c to quickly and simply identify the defective adherence location.

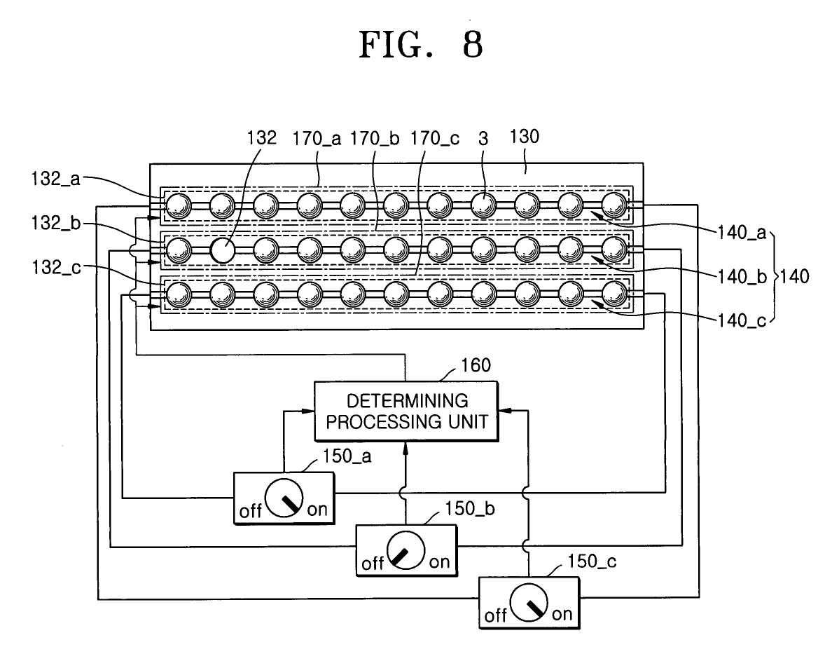

FIG. 7 is a sectional view of a solder ball-transmitting apparatus according to an embodiment of the present invention and FIG. 8 is a block diagram of a solder ball-transmitting apparatus when the ball-receiving apertures are electrically interconnected.

Referring to FIG. 7, a solder ball-transmitting apparatus 100 with the above-described solder ball-inspecting apparatus includes a solder ball-reservoir 120 and a solder ball-transferring member 170 as well as the solder ball-transmitting tool 130.

The solder ball-reservoir 120 is designed to receive the plurality of solder balls 3 that are to be adhered to the ball-receiving apertures 132 of the solder ball-transmitting tool 130 by the solder ball-transferring member 170.

As shown in the FIG. 7, the solder ball-transferring member 170 (e.g., a suction unit such as a vacuum tank) is in communication with the solder ball-transmitting tool 130 to retain the solder balls 3 received in the solder ball-reservoir 120, thereby adhering the solder balls 3 to the respective ball-receiving apertures 132. The solder ball-transferring member 170 is not limited to the above case, but may also be, for example an electromagnet or other device for attracting, retaining and releasing a metallic object. Further, a blower fan may be coupled to the solder ball-reservoir 120 to help the solder balls 3 become attracted to and adhered to the ball-receiving apertures 132. Other type of members that can allow the solder balls to be adhered to the ball-receiving apertures may also be suitable.

As shown in FIG. 8, the solder ball-transmitting apparatus 100 includes the electric connection-detecting unit 150 and the determining-processing unit 160. The electric connection-detecting unit 150 detects the electric connection of the electric pattern 140. The determining-processing unit 160 determines if the solder balls 3 are correctly received in the ball-receiving apertures 132 according to the detecting results of the electric connection-detecting unit 150.

In this case, when the determining-processing unit 160 determines that the first and second ends of the electric pattern 140 are not electrically interconnected, the solder ball-transferring member is controlled such that the adhering force of the solder balls 3 to the ball-receiving apertures 132 is increased. That is, when the solder ball-transferring member 170 includes the suction unit provided above the solder ball-transferring tool 130, the suction force of the suction unit is increased to more effectively retain the solder balls receiving in the solder ball-reservoir, thereby increasing the adhering force of the solder balls 3 to the ball-receiving apertures 132.

Particularly, the determining-processing unit 160 may be electrically connected to the solder ball-transferring member 170 so that the adhering force of the solder ball-transferring member 170 can be automatically controlled.

When the plurality of electric pattern units 141 are arranged in groups such as rows 140a, 140b and 140c that are formed on the solder ball-transmitting tool 130 as shown in FIGS. 6 and 8, the solder ball-transferring member 170 may be designed to provide independent adhering force to each of the ball-receiving aperture groups 132_{—}a, 132_{—}b and 132_{—}c. To realize this, the solder ball-transferring member 170 may comprise independent members 170_{—}a, 170_{—}b and 170_{—}c providing separate adhering forces to the respective ball-receiving aperture groups 132_{—}a, 132_{—}b and 132_{—}c. Alternatively, the solder ball-transferring member 170 may be provided in a single member with valves, baffles or the like so that the member 170 can provide independent adhering force to each of the ball-receiving aperture groups 132_{—}a, 132_{—}b and 132_{—}c. Therefore, the electric patterns 140_{—}a, 140_{—}b and 140_{—}c are connected to the respective electric connection-detecting units 150_{—}a, 150_{—}b and 150_{—}c to quickly identify the defective adherence. As can be appreciated, such an arrangement would help a user correct a solder ball adherence problem without having to release all of the plurality of balls 3 and re-adhere the same. To this end, the adhering force of the ball-receiving group 132_{—}b having the defective connection identified by unit 150_{—}b can be increased by member 170_{—}b to quickly correct the missing solder ball 3 condition.

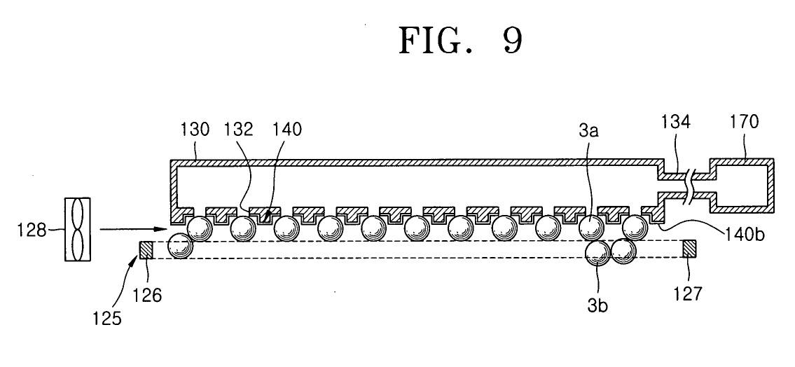

As shown in FIGS. 7 and 9, the solder ball-transmitting apparatus 100 may further include a ball adherence-detecting unit 125 and a ball separation-detecting unit 128. The ball adherence-detecting unit 125 determines if the solder balls 3 received in the ball-receiving apertures 132 are adhered to each other (e.g., balls 3a and 3b as shown in FIG. 9). A ball-bridging phenomenon where the balls are adhered to each other may be caused by static electricity, humidity or polluted air in the solder ball-reservoir 120. Therefore, when the ball-bridging phenomenon is incurred, it is likely that one of the bridged balls is not received in the corresponding ball receiving aperture 132 and/or that the bridged balls could cause a defect in the semiconductor package. Therefore, the ball adherence detecting unit 125 detects if the solder balls 3 are bridged.

In order to detect if the balls are bridged, the ball adherence-detecting unit 125 may use an optical sensor (e.g., visible or infrared light) or an ultrasonic sensor. For example, as shown in FIG. 9, the unit 125 may comprise a light emitter 126 and a light receiver 127 (e.g., a photosensor). So that the emitter 126 and receiver 127 are arranged and aligned beside the ball receiving aperture 132 at a height equal to or slightly lower than a bottom of the solder ball 3 that is received in the ball-receiving aperture 132. Therefore, when the solder balls 3 are correctly received in the respective ball-receiving apertures 132, a light beam is transmitted from emitter 126 to receiver 127, which receives all of the light emitted from the emitter 126 (i.e., the beam is unobstructed). On the contrary, when the solder balls 3 are not correctly received in the respective ball-receiving apertures 132 (e.g., bridged), the light receiver 127 may not receive any of the light emitted from the light emitter 126 or may receive a small amount of the light beam. Thus, it becomes possible to identify if there is a ball-bridging phenomenon (i.e., one or more solder balls 3 blocking the light beam).

In this case, the ball adherence-detecting unit 125 is disposed on the solder ball-reservoir 120, but the unit 125 may be disposed elsewhere, for example on the transmitting tool 130. As shown in FIG. 7, the ball adherence-detecting unit 125 may be disposed on a side portion of the solder ball-reservoir 120 at a height that is equal to or slightly lower than a bottom of the solder ball received in the ball-receiving aperture 132.

When the ball adherence-detecting unit 125 detects that the solder balls 3 are adhered or bridged to each other, the adhered solder balls should be separated. Therefore, the solder ball-transmitting apparatus may further include a ball separation unit 128 for separating the bridged solder balls 3a and 3b (FIG. 9) from each other. In this case, the ball separation unit 128 may include a blower unit that selectively directs operational fluid to a surface of the ball transmitting tool 130 proximate one or more ball receiving apertures 132. The operational fluid may be, for example, an inert gas or air. By blowing the operational fluid to the bridged solder balls, it becomes possible to separate the bridged solder balls from each other.

As can be appreciated, the ball separation unit 128 should be configured such that the blowing force of the operational fluid is lower than the adhering force from unit 170 that retains the solder balls 3 in the ball-receiving apertures 132. In this way the correctly retained solder balls 3 are not separated from the ball-receiving apertures 132 by the blowing force.

FIG. 10 is a flowchart of a solder ball-inspecting method according to an embodiment of the present invention.

Referring to FIGS. 10 and 7, a solder ball-inspecting method of the present invention includes electrically interconnecting the ball-receiving apertures 132 receiving the respective solder balls 3 (S10), detecting if the ball-receiving apertures are electrically interconnected (S20), and determining if the solder balls 3 are correctly received in the respective ball-receiving apertures 132 in accordance with the electric connection-detecting result (S30). That is, it can be easily determined if the solder balls 3 are correctly received in the respective receiving apertures 132 by detecting if the adjacent ball-receiving apertures 132 receiving the respective solder balls 3 are electrically interconnected.

The process (S10) for electrically interconnecting the ball-receiving apertures 132 may include forming at least one electric pattern 140 comprised of a plurality of unit patterns 141 interconnecting the two ball-receiving apertures 132 (S11) and adhering the solder balls 3 to the respective ball-receiving apertures 132 formed on the solder ball-transmitting tool (S12).

Here, the electric pattern 140 may be formed of Copper or other conductive material known in the art that is patterned or otherwise applied or disposed between the ball-receiving apertures 132. In this case, the electric pattern 140 includes at least one group (e.g., row) including a plurality of unit patterns 141 interconnecting a group of adjacent ball-receiving apertures 132. The unit patterns 141 each have a first end that connects to a part of a first ball-receiving aperture 132 and a second end that connects to a part of a second ball-receiving aperture 132 adjacent the first ball-receiving aperture 132 such that adjacent unit patterns are insulated from each other by the ball-receiving aperture 132 (i.e., the pattern 140 is a discontinuous circuit made of unit patterns 141). When the solder balls 3 are correctly received in the ball-receiving apertures 132, the discontinuous circuit of unit patterns 141 is completed (i.e., electrically interconnected) by the solder balls 3 that are formed of conductive material.

Therefore, when the solder balls 3 are adhered to the receiving-apertures 132 formed between unit patterns 141, the first and second ends 140a and 140b of the electric pattern 140 are electrically interconnected. When the solder ball is not adhered to at least one receiving-aperture formed between the unit patterns 141, the first and second ends 140a and 140b of the electric pattern 140 comprised of the unit patterns 141 is not electrically interconnected.

Therefore, in the process (S20) for detecting if the ball-receiving apertures 132 are electrically interconnected, it is detected if the first and second ends 140a and 140b of the electric pattern 140 are electrically interconnected. One of the methods for detecting the electric connection of the electric pattern 140 is to detect if current flows between the first and second ends 140a, 140b of the electric pattern 140.

After determining in step S20 that the first and second ends of the electric pattern 140 are electrically interconnected, next in step S31 it is determined whether the solder balls 3 are correctly received in the ball-receiving apertures 132. Alternatively, in step S32 it is determined which of the ball-receiving apertures 132 have not correctly received a solder ball 3 (e.g., one or more apertures 132 may be empty) for example by using the determining-processing unit 160 with multiple connection-detecting units 150 (e.g., units 150_{—}a, 150_{—}b, and 150_{—}c of FIGS. 6 and 8).

When it is determined in step S32 which one or more apertures 132 have not correctly received a solder ball 3, the adhering force to those one or more ball-receiving apertures 132 is increased (S40). The adhering force may be increased by increasing a force of the solder ball-transferring member 170 (e.g., a suction unit) connected to the ball-receiving apertures 132. For example, by increasing the suction force, ball-receiving apertures 132 devoid of solder balls 3 can more readily attract and seat a solder ball 3 therein.

Meanwhile, the electric pattern 140 may be designed to linearly interconnect all of the ball-receiving apertures 132. Therefore, at least one of the solder balls 3 are not correctly retained on the corresponding receiving aperture 132, the first and second ends 140a and 140b of the electric pattern 140 are not to be electrically interconnected. As a result, it becomes possible to determine if all of the solder balls 3 are correctly received in the respective ball-receiving apertures 132.

Alternatively, a plurality of electric patterns 140 may be formed on the single solder ball-transmitting tool 130. In this case, the electric pattern 140 may be designed to interconnect a part of the ball-receiving apertures 132 formed on the ball-transmitting tool 130. The electric patterns may be designed to interconnect the ball-receiving apertures 132 arranged in lateral or longitudinal directions. Alternatively, the electric patterns may be formed to define a single circle.

In this case, as shown in FIG. 8, independent adhering force may be applied to each of the ball receiving aperture groups 132_{—}a, 132_{—}b and 132_{—}c. Therefore, the electric patterns 140_{—}a, 140_{—}b and 140_{—}c are connected to the respective electric connection-detecting units 150_{—}a, 150_{—}b and 150_{—}c to quickly identify the defective adherence. The adhering force of the ball-receiving group 132_{—}b having the defective connection is increased to quickly complete the adherence of the solder ball 3.

Meanwhile, although an electrical interconnection between the ends 140a, 140b of the pattern 140 may exist, the ball-bridging phenomenon may be incurred, for example, due to static electricity, humidity or polluted air proximate the solder ball-transmitting tool 130 or in the reservoir 120.

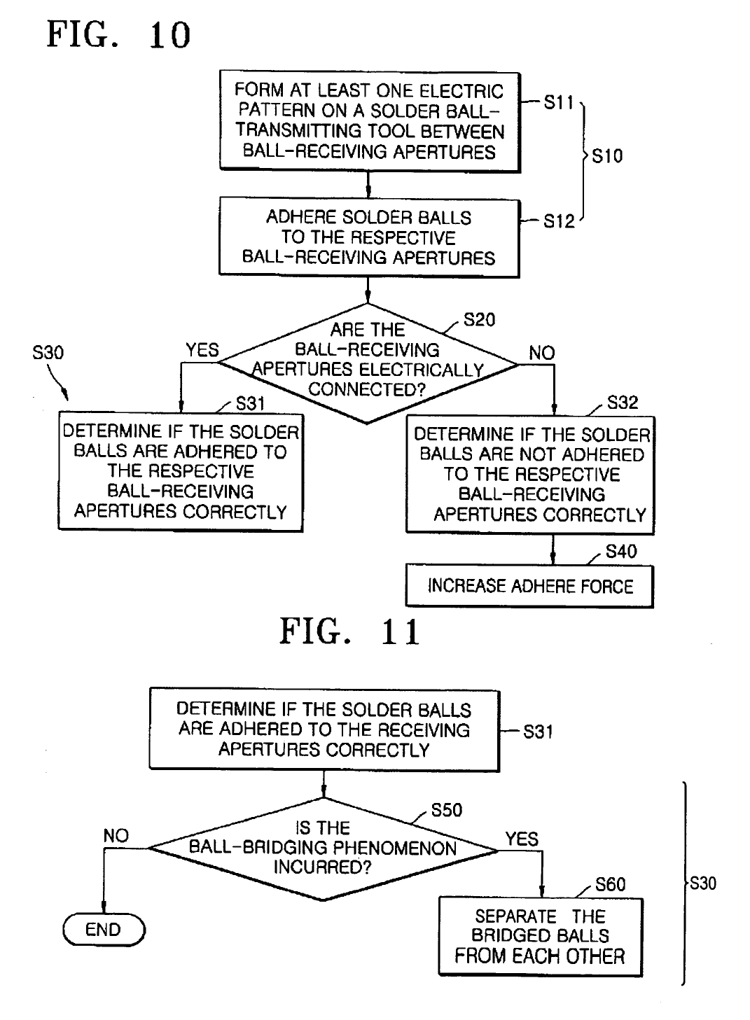

Therefore, as shown in FIG. 11, step S30 may further comprise the steps S50 and S60 for determining whether the ball-bridging phenomenon is incurred. In step S50, when the ball-bridging phenomenon is incurred, the bridged-balls are then separated from each other in step S60.

As shown in FIGS. 10 and 11, the processes S50 and S60 are performed after step S20 where it is determined if the solder balls are correctly received in the respective ball-receiving apertures. However, the processes S50 and S60 may be performed before or after other steps in the method, for example, before step S20 or after step S20 and before step S32 when it is determined that the solder balls are not correctly received in the ball-receiving apertures 132. In step S60, the bridged balls (e.g., balls 3a and 3b shown in FIG. 9) may be separated from each other by blowing fluid toward the bridged balls. The fluid may be, for example, an inert gas or air. At this point, the blowing force must be lower than the adhering force of the solder balls 3 to the ball-receiving apertures 132 so that the solder balls 3 are not separated from the ball-receiving apertures 132 by the blowing force. Indeed, after step S60, the method can perform step S20 for again determining adherence of the solder balls 3 to the apertures 132. Thereafter, steps such as S31, S32, S40, S50 and S60 may be performed.

After the solder ball-inspecting process is finished, the solder balls 3 are disposed on the printed circuit board or the semiconductor wafer and the solder bump is formed through a reflow-oven.

According to the above-described present invention, the correct retaining of the solder balls in the ball-receiving apertures can be identified without using a camera. Therefore, since there is no need to perform the image process, the inspecting process can be more quickly and easily performed. Particularly, by detecting if the solder balls are correctly received in the ball-receiving apertures by determining if the ball-receiving apertures are electrically interconnected, the inspection can be more accurately realized.

Furthermore, since there is no need of the photographing camera and the image processor, the size of the solder ball-transmitting apparatus can be reduced.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An apparatus for placing a plurality of solder balls on a semiconductor component, the apparatus comprising:
a solder ball-transmitting tool including a plurality of apertures configured to receive and retain the plurality of solder balls, an electrically conductive pattern disposed between each aperture of the plurality of apertures and having first and second ends, the first and second ends being electrically interconnected when the plurality of solder balls are received in the plurality of apertures;
a detecting unit connected to the first and second ends for measuring an electric connection therebetween; and
a processing unit for determining if the plurality of solder balls is correctly received in the plurality of apertures according to the electric connection.

2. The apparatus of claim 1, wherein the electrically conductive pattern comprises a plurality of unit patterns, each unit pattern of the plurality interconnecting two adjacent apertures of the plurality of apertures.

3. The apparatus of claim 1, further comprising a reservoir for storing solder balls.

4. The apparatus of claim 3, wherein the solder ball-transmitting tool further includes a solder ball-transferring member in communication with the plurality of apertures, the solder ball-transferring member attracting solder balls from the reservoir to the plurality of apertures and releasing attracted solder balls to the semiconductor component.

5. The apparatus of claim 4 wherein the solder ball-transferring member comprises a vacuum means.

6. The apparatus of claim 1 wherein the detecting unit is selected from the group consisting of a current meter, voltage meter, resistance meter and a continuity meter.

7. An apparatus for inspecting placement of solder balls on a semiconductor component by a solder ball-transmitting tool including a solder ball reservoir storing a plurality of solder balls, a plurality of apertures configured to receive the plurality of solder balls, a solder ball-transferring member in communication with the plurality of apertures for attracting solder balls from the reservoir and retaining the solder balls in the apertures and an electrically conductive pattern disposed between each aperture of the plurality of apertures and having first and second ends, the apparatus comprising:
a detecting unit that connects with the first and second ends for determining an electrical characteristic of the electrically conductive pattern; and
a processing unit in communication with the detecting unit for determining reception of the plurality of solder balls in the plurality of apertures according to the electrical characteristic.

8. The apparatus of claim 7 wherein the processing unit communicates with the solder ball-transferring member to increase an attraction force at an aperture of the plurality relative to the electrical characteristic.

9. The apparatus of claim 7, further comprising;
a ball-bridging detecting unit for detecting if at least two solder balls of the plurality that are being retained in the plurality of apertures are electrically connected by at least one bridging ball; and
a ball-separating unit for separating the bridging ball from the at least two solder balls.

10. The apparatus of claim 9, wherein the ball-bridging detecting unit comprises a light emitter and a light sensor, the light emitter outputting a light beam and the light sensor being aligned with the light emitter to receive the light beam, and wherein the light sensor and light emitter are configured proximate the plurality of apertures so the light beam is unobstructed when the plurality of solder balls are retained in the plurality of apertures.

11. The apparatus of claim 9, wherein the ball-separating unit comprises a blowing member for blowing a fluid at the bridging ball.

12. A method for placing a solder ball on a semiconductor component by a solder ball-transmitting tool including an aperture configured to receive the solder ball and a solder ball-transferring member in communication with the aperture for attracting the solder ball, the method comprising:
disposing an electrically conductive pattern on a surface of the tool so that the pattern is interrupted by the aperture;
connecting a detecting unit to first and second ends of the electrically conductive pattern;
attracting the solder ball to the aperture;
determining an electrical characteristic of the electrically conductive pattern with the detecting unit; and
relative to the determining step, repeating the attracting and determining step or transmitting the solder ball to the semiconductor component.

13. The method of claim 12 wherein the step of attracting comprises activating the solder ball-transferring member.

14. The method of claim 12 wherein the determining step comprises measuring at least one of current, voltage and resistance relative to the electrically conductive pattern.

15. The method of claim 12 wherein the step of transmitting comprises deactivating the solder ball-transferring member to release the solder ball from the aperture.

16. The method of claim 12 further comprising:
detecting if a second solder ball is adhered to the solder ball in the aperture; and
separating the second solder ball from the solder ball in the aperture.

17. The method of claim 16 wherein the detecting step comprises:
positioning a light source on one side of the aperture;
aligning a light receiver with the light source, the light receiver being positioned on another side of the aperture;
generating a light beam that traverses the aperture from the light source to the light receiver; and
detecting a break in the light beam.

18. The method of claim 16 wherein the separating step comprises blowing a fluid toward the second solder ball.

19. The method of claim 18 wherein the fluid comprises at least one of an inert gas and air.
